(19) United States
(12) Patent Application Publication
(10) Pub. No.: US 2013/0299874 A1
(43) Pub. Date: Nov. 14, 2013

(54) TMAH RECESS FOR SILICON GERMANIUM IN POSITIVE CHANNEL REGION FOR CMOS DEVICE

(71) Applicants: Joanna Wasyluk, Dresden (DE); Berthold Reimer, Dresden (DE); Carsten Reichel, Dresden (DE); Jamie Schaeffer, Dresden (DE); Yew Tuck Chow, Dresden (DE); Stephan Kronholz, Dresden (DE); Andreas Ott, Dresden (DE)

(72) Inventors: Joanna Wasyluk, Dresden (DE); Berthold Reimer, Dresden (DE); Carsten Reichel, Dresden (DE); Jamie Schaeffer, Dresden (DE); Yew Tuck Chow, Dresden (DE); Stephan Kronholz, Dresden (DE); Andreas Ott, Dresden (DE)

(73) Assignee: GLOBALFOUNDRIES Singapore Pte. Ltd., Singapore (SG)

(21) Appl. No.: 13/468,777

(22) Filed: May 10, 2012

(51) Int. Cl. H01L 27/092; H01L 21/20

(52) U.S. Cl. 257/192; 438/478; 257/E21.09; 257/E27.062

(57) ABSTRACT

CMOS devices are enhanced by forming a recess in the positive channel for depositing SiGe. Embodiments include providing a positive channel region and a negative channel region in a silicon substrate for a CMOS device, with an STI region therebetween; removing a native oxide from above the positive channel region to expose a silicon substrate; forming a recess in the silicon substrate in the positive channel region adjacent the STI region; and depositing SiGe in the recess in the positive channel region, where an upper surface of the SiGe is substantially level with an upper surface of the negative channel region.

### TECHNICAL FIELD

The present disclosure relates to fabrication of semiconductor devices, and more particularly to CMOS devices in 32 nanometer (nm) technology nodes and beyond.

### BACKGROUND

Conventional processes for forming CMOS devices by depositing channel silicon germanium (SiGe) in positive channel field effect transistor (PFET) results in topography issues that can lower device yield and degrade device performance characteristics. For example, such fabrication techniques can result in an N- to P-active step height and the formation of divots in the shallow trench isolation (STI) region. Such features might result in encapsulation breaches during subsequent process steps, and such encapsulation breaches can lead to missing high-K material in the high-K metal gate, thereby resulting in higher Vₜ and lower device yield.

FIG. 4 shows an example of a CMOS formed using such conventional processes. In FIG. 4, a silicon substrate 110 is provided with a PFET or positive channel region 112, a negative channel field effect transistor (NFET) or negative channel region 114, and a STI region 116. An oxide hard mask layer 118 is provided on an upper surface 126 of the silicon substrate 110 above the negative channel region 114. A portion of the native oxide is removed above the positive channel region 112 to expose an upper surface 125 of the silicon substrate 110, without etching into the silicon substrate 110. SiGe 130 is then deposited on the upper surface 125. However, as can be seen in FIG. 4, the conventional process results in an N- to P-active step height, as can be seen by the step thickness 128 between an upper surface 131 of the SiGe 130 in the positive channel region 112 and the upper surface 126 above the negative channel region 114. Furthermore, as can be seen in FIG. 5, which shows a profile of the positive channel region 112, a profile of the SiGe 130 is not planar, but rather has a distended, arched shape. Such an arched shape profile can have negative effects on device performance.

A need therefore exists for methodology enabling the cost-effective fabrication of CMOS devices including PFETs with channel SiGe having high yield and enhanced device performance.

### SUMMARY

An aspect of the present disclosure is a method of forming a CMOS with improved topography that may further result in higher yield and better device performance.

Another aspect of the present disclosure is a CMOS with improved topography that may further result in higher yield and better device performance.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including providing a positive channel region and a negative channel region in a silicon substrate for a CMOS device, with an STI region therebetween, removing a native oxide from above the positive channel region to expose the silicon substrate, forming a recess in the silicon substrate in the positive channel region adjacent the STI region, and depositing SiGe in the recess in the positive channel region, wherein an upper surface of the SiGe is substantially level with an upper surface of the negative channel region.

Other aspects include forming the recess using an etching solution that does not etch the STI region. Further aspects include forming the recess using a TMAH solution, for example containing a concentration of 1% to 100% TMAH, e.g. a concentration of 10% to 25% TMAH. Another aspect includes forming the recess by applying the TMAH solution at a temperature within a range of 25° C. to 100° C., e.g. a concentration of 10% to 25% TMAH for a time within a range of 10 seconds to 60 seconds. Additional aspects include removing the native oxide from above the positive channel region using a diluted hydrofluoric acid (dHF) solution. Another aspect includes performing a cleaning of the recess prior to depositing the SiGe therein, for example using a dHF solution. Further aspects include forming the recess to a depth of from 2 nm to 20 nm. An exemplary recess depth is from 8 to 10 nm. Other aspects include the SiGe formed in the positive channel region having a substantially planar profile.

Another aspect of the present disclosure is a CMOS device including an STI region, a negative channel region adjacent to the STI region, and a positive channel region adjacent to the STI region at a location opposite to the negative channel region, wherein the positive channel region has a recess formed therein, the recess having SiGe deposited therein, and wherein an upper surface of the SiGe is substantially level with an upper surface of the negative channel region.

Yet another aspect of the present disclosure is a method including providing a positive channel region and a negative channel region in a silicon substrate for a CMOS device, with a shallow trench isolation (STI) region therebetween; etching a recess in the positive channel region adjacent the STI region using a TMAH solution, and epitaxially growing SiGe in the recess in the positive channel region, wherein an upper surface of the SiGe is substantially level with an upper surface of the negative channel region, and wherein the SiGe formed in the positive channel region has a substantially planar profile.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1D schematically illustrate a process flow for fabricating a CMOS structure having a PFET channel SiGe formed in a recess, according to an exemplary embodiment;

FIG. 2 illustrates a profile of a positive channel region of the CMOS formed using the process depicted in FIGS. 1A through 1D, according to an exemplary embodiment;

FIG. 3 a flowchart of a process flow for fabricating a CMOS structure having a channel SiGe formed in a recess, according to an exemplary embodiment;

FIG. 4 schematically illustrates a CMOS structure having a PFET channel SiGe fabricated using conventional processes; and

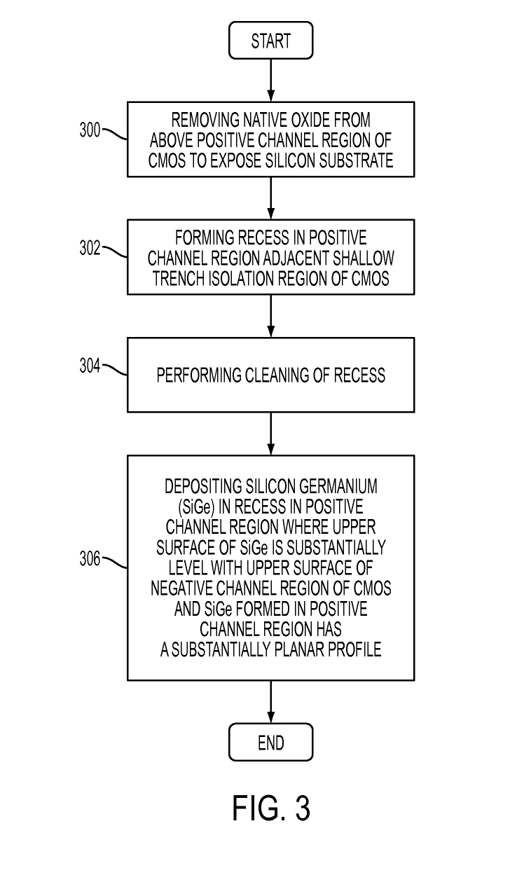

FIG. 5 illustrates a profile of a positive channel region of the CMOS depicted in FIG. 4 fabricated using conventional processes.

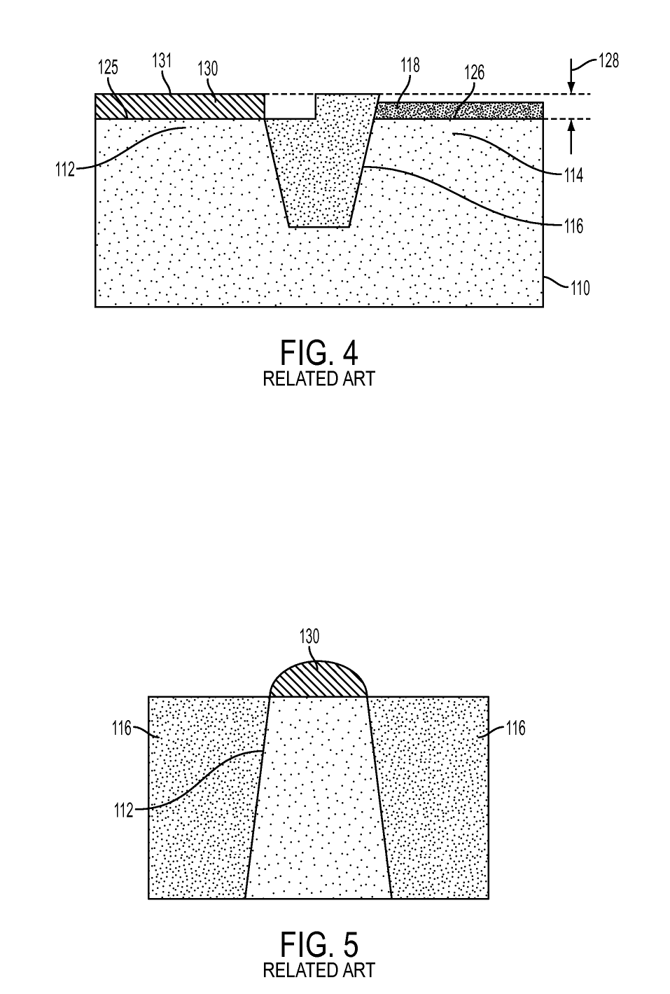

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present invention provides a method of forming a CMOS structure having a PFET channel SiGe with improved topography that may result in higher yield and enhanced device performance. Embodiments of the invention provide numerous advantages. For example, with such embodiments, little or no NFET active to PFET active step height is present, which reduces concerns for encapsulation breaches during subsequent process steps, as can occur with conventional CMOS structures having such a step height. Also, the embodiments provide CMOS fabrication techniques that decrease or eliminate etching of the STI area. Also, compared with conventional CMOS structures, the embodiments provide SiGe formation in the positive channel region with a substantially planar profile, thereby providing a more defined intrinsic SiGe channel region, which may advantageously influence device performance by influencing the effective gate length.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

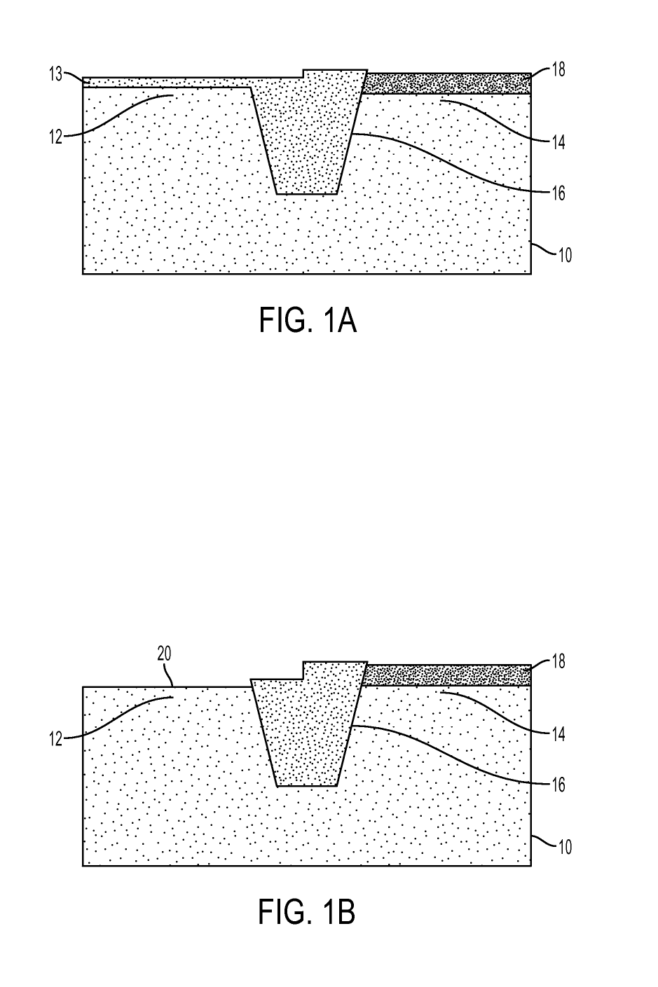

FIGS. 1A through 1D schematically illustrate a process flow for fabricating a CMOS structure having a PFET channel SiGe formed in a recess, according to an exemplary embodiment.

Adverting to FIG. 1A, a silicon substrate (or wafer) 10 is provided with a PFET or positive channel region 12, an NFET or negative channel region 14, and an STI region 16. The STI region is formed of silicon dioxide, and a native oxide region 13 is above the positive channel region 12. An oxide hardmask layer 18 is provided on an upper surface of the silicon substrate 10 above the negative channel region 14.

As shown in FIG. 1B, an etch process can be performed to remove the native oxide 13 in a region above the positive channel region 12 and a portion of the STI region 16 as well as a portion of hard mask 18 on the negative channel region 14. A portion of the native oxide is removed above the positive channel region 112 to expose an upper surface 20 of the silicon substrate 10, without etching into the silicon substrate 10. The etching of the native oxide 13 can be performed using a diluted hydrofluoric acid (dHF) solution.

Then, as shown in FIG. 1C, an etch process can be performed to remove, for example, a portion of the silicon substrate in the positive channel region 12 to form a recess 22. The recess 22 is formed in the positive channel region using a tetramethylammonium hydroxide (TMAH) solution. The TMAH solution can contain a concentration of 1% to 100% TMAH, for example a concentration of 10% to 25% tetramethylammonium hydroxide. The recess 22 can be formed by applying the TMAH solution at a temperature within a range of 25° C. to 100° C. for a time within a range of 10 seconds to 60 seconds. The recess 22 can be formed having a depth 28 of from 2 nm to 20 nm, for example 8 nm to 10 nm. Note that the recess 22 has a characteristic shape with Si sidewalls 23a, 23b on sides of the recess 22.

Following the etching of the recess 22, a cleaning of the recess 22 can be performed prior to depositing the SiGe therein. A pre-epitaxial cleaning process can be performed using a dHF solution or APM/dHF. An exemplary cleaning process uses a solution of from 10 dHF to 30 dHF.

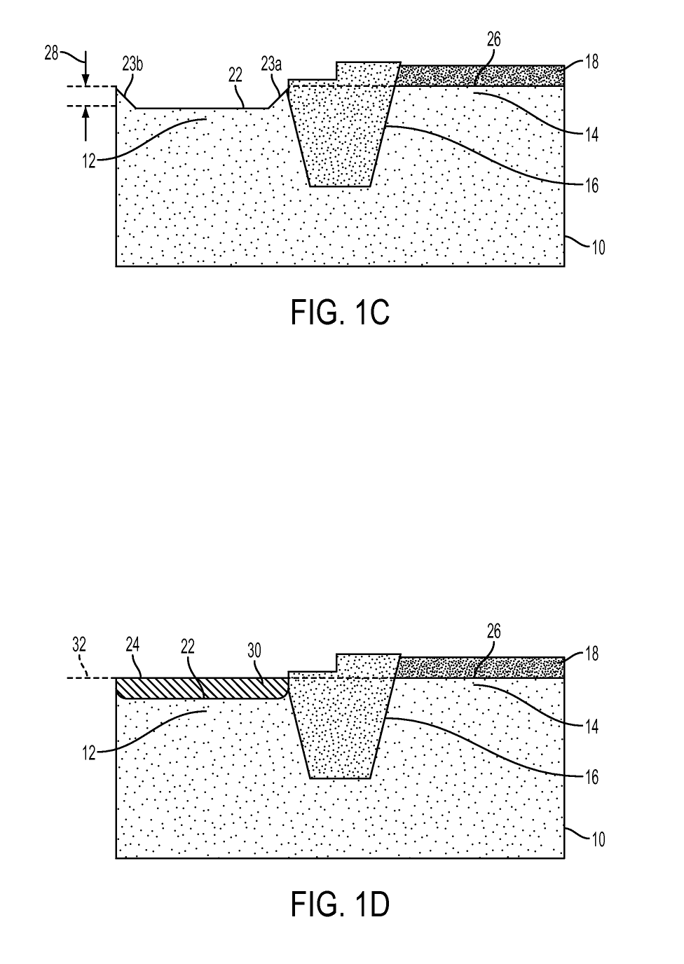

Then, as shown in FIG. 1D, SiGe 30 is deposited in the recess 22, for example by epitaxially growing SiGe on the silicon substrate 10, and various topography and defect inspections can then be performed. By forming the SiGe 30 in this manner, little or no N- to P-active step height can be formed. The SiGe 30 is formed to have an upper surface 24 that is level with or substantially level with an upper surface 26 of the silicon substrate in the negative channel region 14, as shown by dashed line 32. Thus, unlike with conventional processes, there is no step thickness between the upper surface 24 of the SiGe 30 in the positive channel region 12 and the upper surface 26 above the negative channel region 14. Furthermore, as can be seen in FIG. 2, which shows a profile of the positive channel region 12, a profile of the SiGe 30 is planar or substantially planar in shape, which may advantageously influence device performance.

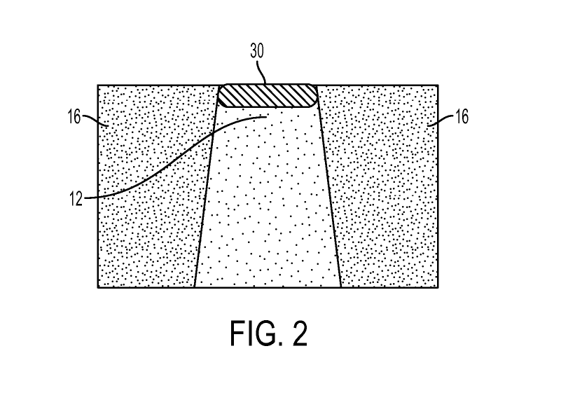

FIG. 3 shows a flowchart of a process flow for fabricating a CMOS structure having a channel SiGe formed in a recess, according to an exemplary embodiment. In step 300, a native oxide is removed from above a positive channel region of a CMOS device to expose a silicon substrate. In step 302, a recess is formed in the positive channel region adjacent to a STI region of the CMOS. The recess can be formed using a TMAH solution, for example at a concentration of 1% to 100% TMAH, e.g. a concentration of 10% to 25% TMAH. The recess 22 can be formed by applying the TMAH solution at a temperature within a range of 25° C. to 100° C. for a time within a range of 10 seconds to 60 seconds. The recess 22 can be formed having a depth 28 of from 2 nm to 20 nm, e.g. 8 nm to 10 nm.

In step 304, a cleaning process can be performed to clean the recess. And, in step 306, SiGe is deposited in the recess in the positive channel region such that an upper surface of the SiGe is substantially level with an upper surface of the negative channel region of the CMOS, and such that the SiGe formed in the positive channel region has a substantially planar profile.

Thus, embodiments are provided to recess a silicon substrate with TMAH solution in a PFET of a CMOS structure to form a flat Si topography in a center recess in the P-active region and characteristic Si sidewalls and STI sidewalls on the edges of the P-active region. This characteristic shape of recessed Si allows for a more defined profile of channel SiGe across the width of the PFET region, which impacts performance of the device. The recess formed with a TMAH solution allows for p-channel SiGe deposition with no N-active to P-active step height. An advantage of TMAH chemistry is that it does not etch the silicon dioxide of the STI region, which decreases divot formation with relation to the P-active region in comparison to conventional processes. After recess formation and SiGe deposition, the PFET active region is advantageously on the same level as the NFET active region.

Thus, embodiments advantageously provide no NFET active to PFET active step height. Also, embodiments advantageously decrease of divot formation with relation to the P-active region, which results in better encapsulation and therefore also results in better yield. Also, embodiments advantageously provide more defined intrinsic SiGe channel regions, which may influence device performance.

The embodiments of the present disclosure can achieve several technical effects, particularly in forming cost effective CMOS devices with PFETs using SiGe with high yield and enhanced device performance. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly for 32 nm and 28 nm technology nodes.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a positive channel region and a negative channel region in a silicon substrate for a CMOS device, with a shallow trench isolation (STI) region therebetween;
removing a native oxide from above the positive channel region to expose a silicon substrate;
forming a recess in the silicon substrate in the positive channel region adjacent the STI region; and
depositing silicon germanium (SiGe) in the recess in the positive channel region,
wherein an upper surface of the SiGe is substantially level with an upper surface of the negative channel region.

2. The method according to claim 1, comprising forming the recess using an etching solution that does not etch the STI region.

3. The method according to claim 1, comprising forming recess in the positive channel region using a tetramethylammonium hydroxide (TMAH) solution.

4. The method according to claim 3, wherein the TMAH solution contains a concentration of 1% to 100% TMAH.

5. The method according to claim 3, wherein the TMAH solution contains a concentration of 10% to 25% TMAH.

6. The method according to claim 4, comprising forming the recess by applying the TMAH solution at a temperature within a range of 25° C. to 100° C. for a time within a range of 10 seconds to 60 seconds.

7. The method according to claim 1, comprising removing the native oxide from above the positive channel region using a diluted hydrofluoric acid (dHF) solution.

8. The method according to claim 1, further comprising performing a cleaning of the recess prior to depositing the SiGe therein.

9. The method according to claim 8, comprising performing the cleaning using a dHF solution.

10. The method according to claim 1, comprising forming the recess to a depth of from 2 nm to 20 nm.

11. The field effect transistor according to claim 1, wherein the SiGe formed in the positive channel region has a substantially planar profile.

12. A CMOS device comprising:
a shallow trench isolation (STI) region;
a negative channel region adjacent to the STI region; and
a positive channel region adjacent to the STI region at a location opposite to the negative channel region,
wherein the positive channel region has a recess formed therein, the recess having silicon germanium (SiGe) deposited therein, and
wherein an upper surface of the silicon germanium is substantially level with an upper surface of the negative channel region.

13. The CMOS device according to claim 12, wherein the recess is formed in the positive channel region using a tetramethylammonium hydroxide (TMAH) solution.

14. The CMOS device according to claim 13, wherein the TMAH solution contains a concentration of 1% to 100% TMAH, and wherein the recess is formed by applying the TMAH solution at a temperature within a range of 25° C. to 100° C. for a time within a range of 10 seconds to 60 seconds.

15. The CMOS device according to claim 12, wherein the recess has a depth of from 2 nm to 20 nm.

16. The CMOS device according to claim 12, wherein the SiGe formed in the positive channel region has a substantially planar profile.

17. A method comprising:
providing a positive channel region and a negative channel region in a silicon substrate for a CMOS device, with a shallow trench isolation (STI) region therebetween;
etching a recess in the positive channel region adjacent the STI region using a tetramethylammonium hydroxide (TMAH) solution; and
epitaxially growing silicon germanium (SiGe) in the recess in the positive channel region,
wherein an upper surface of the SiGe is substantially level with an upper surface of the negative channel region, and
wherein the SiGe formed in the positive channel region has a substantially planar profile.

18. The method according to claim 17, wherein the TMAH solution contains a concentration of 1% to 100% TMAH, and comprising etching the recess by applying the TMAH solution at a temperature within a range of 25° C. to 100° C. for a time within a range of 10 seconds to 60 seconds.

19. The method according to claim 17, further comprising removing native oxide from above the positive channel region using a diluted hydrofluoric acid (dHF) solution, prior to etching the recess.

20. The method according to claim 17, comprising forming the recess to a depth of from 2 nm to 20 nm.
